(19) United States
(12) Patent Application Publication
(10) Pub. No.: US 2025/0212624 A1
(43) Pub. Date: Jun. 26, 2025

(54) LIGHT-EMITTING DEVICE

(71) Applicant: Innolux Corporation, Miaoli County (TW)

(72) Inventors: Yu-Chia Huang, Miaoli County (TW); Tsung-Han Tsai, Miaoli County (TW); Kuan-Feng Lee, Miaoli County (TW)

(73) Assignee: Innolux Corporation, Miaoli County (TW)

(21) Appl. No.: 18/963,569

(22) Filed: Nov. 28, 2024

(30) Foreign Application Priority Data
Dec. 26, 2023 (CN) 202311805011.2

(51) Int. Cl. H10K 59/126; H10K 59/35; H10K 59/38; H10K 59/80

(52) U.S. Cl. CPC H10K 59/126; H10K 59/353; H10K 59/38; H10K 59/878

(57) ABSTRACT

A light-emitting device including a substrate, an insulating layer, a first light-emitting unit, and a first light-shielding layer is provided. The insulating layer is disposed on the substrate and includes a first opening. The first light-emitting unit is disposed in the first opening. The first light-shielding layer is disposed on the insulating layer. In a cross-sectional view, the first light-shielding layer includes a first light-shielding portion and a second light-shielding portion adjacent to the first light-shielding portion. A first overlapping area of the first light-shielding portion is defined by a portion of the first light-shielding portion that overlaps the first opening. A second overlapping area of the second light-shielding portion is defined by a portion of the second light-shielding portion that overlaps the first opening, and the first overlapping area is different from the second overlapping area.

### CROSS-REFERENCE TO RELATED APPLICATION

This application claims the priority benefit of China application serial no. 202311805011.2, filed on Dec. 26, 2023. The entirety of the above-mentioned patent application is hereby incorporated by reference herein and made a part of this specification.

### BACKGROUND

### Technical Field

The disclosure relates to an electronic device, and particularly relates to a light-emitting device.

### Description of Related Art

Most conventional electronic devices are designed to have a left-right symmetrical or up-down symmetrical viewing angle. However, in some applications (such as automotive), an asymmetric viewing angle design is required to meet the user's needs.

### SUMMARY

The disclosure is directed to a light-emitting device, which has an asymmetric viewing angle design.

In an embodiment of the disclosure, the light-emitting device includes a substrate, an insulating layer, a first light-emitting unit, and a first light-shielding layer. The insulating layer is disposed on the substrate and includes a first opening. The first light-emitting unit is disposed in the first opening. The first light-shielding layer is disposed on the insulating layer. In a cross-sectional view, the first light-shielding layer includes a first light-shielding portion and a second light-shielding portion adjacent to the first light-shielding portion. A first overlapping area of the first light-shielding portion is defined by a portion of the first light-shielding portion that overlaps the first opening, a second overlapping area of the second light-shielding portion is defined by a portion of the second light-shielding portion that overlaps the first opening, and the first overlapping area is different from the second overlapping area.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a partial top view of a light-emitting device according to a first embodiment of the disclosure.

FIG. 2 and FIG. 3 are respectively schematic cross-sectional views viewing along a section line I-I′ and a section line II-IT′ in FIG. 1.

FIG. 4 to FIG. 8 are respectively partial cross-sectional schematic views of various light-emitting devices according to a second embodiment to a sixth embodiment of the disclosure.

FIG. 9 is a partial top view of a light-emitting device according to a seventh embodiment of the disclosure.

FIG. 10 is a schematic cross-sectional view viewing along a section line III-III′ in FIG. 9.

FIG. 11 is a partial top view of a light-emitting device according to an eighth embodiment of the disclosure.

FIG. 12 is a schematic cross-sectional view viewing along a section line IV-IV′ in FIG. 11.

FIG. 13 to FIG. 15 are respectively partial cross-sectional schematic views of various light-emitting devices according to a ninth embodiment to an eleventh embodiment of the disclosure.

FIG. 16 is a partial top view of a light-emitting device according to a twelfth embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Certain terms are used throughout the specification of the disclosure and the appended claims to refer to specific components. Those skilled in the art should understand that electronic device manufacturers may probably use different names to refer to the same components. This specification is not intended to distinguish between components that have the same function but different names. In the following specification and claims, the terms “including”, “containing”, “having”, etc., are open terms, so that they should be interpreted as meaning of “including but not limited to . . . “.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

One structure (or layer, component, or substrate) described in the disclosure to be located on/above another structure (or layer, component, or substrate) may refer to that the two structures are adjacent and in direct connection, or refers to that the two structures are adjacent and in indirect connection. The indirect connection means that there is at least one intermediate structure (or intermediate layer, intermediate component, intermediate substrate, or intermediate spacer) between the two structures, where a lower surface of one structure is adjacent to or directly connected to an upper surface of the intermediate structure, and an upper surface of another structure is adjacent to or directly connected to a lower surface of the intermediate structure. The intermediate structure may be composed of a single-layer or multi-layer physical structure or a non-physical structure, which is not limited by the disclosure. In the disclosure, when a structure is disposed “on” another structure, it may mean that the structure is “directly” on the other structure, or that the structure is “indirectly” on the other structure, i.e., there is at least one structure sandwiched between the structure and the other structure.

The terms “about”, “substantially” or “approximately” are generally interpreted as within 10% of a given value or range, or as within 5%, 3%, 2%, 1% or 0.5% of a given value or range. In addition, the terms “a range is a first value to a second value” and “a range is between a first value and a second value” mean that the range includes the first value, the second value and other values there between.

The ordinal numbers used in the specification and claims, such as “first”, “second”, etc., are used to modify components, and do not imply and represent the component or these components have any previous ordinal numbers, and do not represent a sequence of one component with another, or a sequence in a manufacturing method. The use of these ordinal numbers is only to make a clear distinction between a component with a certain name and another component with the same name. The same terms may not be used in the claims and the specification, and accordingly, a first component in the specification may be a second component in the claims.

The electrical connection or coupling described in the disclosure may all refer to direct connection or indirect connection. In the case of direct connection, terminals of components on the two circuits are directly connected or connected to each other by a conductor line segment, and in the case of indirect connection, there are switches, diodes, capacitors, inductors, other suitable components, or a combination of the above components between the terminals of the components on the two circuits, but the disclosure is not limited thereto.

In the disclosure, thickness, length and width may be measured by using an optical microscope, and the thickness may be measured through a cross-sectional image in an electron microscope, but the disclosure is not limited thereto. In addition, any two values or directions used for comparison may have certain errors. Moreover, the terms “a given range is from a first value to a second value”, “the given range falls within a range from the first value to the second value” or “the given range is between the first value and the second value” means that the given range includes the first value, the second value, and other values there between. If a first direction is perpendicular to a second direction, an angle between the first direction and the second direction may be between 80 degrees and 100 degrees; if the first direction is parallel to the second direction, the angle between the first direction and the second direction may be between 0 and 10 degrees.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the disclosure, the electronic device may include a light-emitting device, a backlight device, an antenna device, a package device, a sensing device or a splicing device, but the disclosure is not limited thereto. The electronic device may be a bendable or flexible electronic device. The light-emitting device may be a non-self-luminous light-emitting device or a self-luminous light-emitting device. The light-emitting device may, for example, include liquid crystal, light-emitting diodes (LED), fluorescence, phosphor, quantum dot (QD), projection-type light-emitting device, other suitable materials or a combination of the above-mentioned materials. The antenna device may include, for example, a frequency selective surface (FSS), a radio frequency filter (RF-Filter), a polarizer, a resonator, or an antenna. The antenna may be a liquid crystal antenna or a varactor diode antenna. The sensing device may be a sensing device that senses capacitance, light, heat energy or ultrasonic waves, but the disclosure is not limited thereto.

In the disclosure, the electronic device may include electronic components, and the electronic components may include passive components and active components, such as capacitors, resistors, inductors, diodes, transistors, etc. Diodes may include light-emitting diodes, varactor diodes or photodiodes. The light-emitting diodes may include, for example, organic light-emitting diodes (OLEDs), mini LEDs, micro LEDs or quantum dot LEDs, but the disclosure is not limited thereto.

The splicing device may be, for example, a display splicing device or an antenna splicing device, but the disclosure is not limited thereto. It should be noted that the electronic device may be any permutation and combination of the above, but the disclosure is not limited thereto. The package device may be suitable for a wafer-level package (WLP) technology or a panel-level package (PLP) technology, such as a chip first process or a RDL first process. In addition, a shape of the electronic device may be a rectangular shape, a circular shape, a polygonal shape, a shape with curved edges, or other suitable shapes. The electronic device may have peripheral systems such as a driving system, a control system, and a light source system, etc., to support the light-emitting device, the antenna device, the wearable device (for example, including augmented reality or virtual reality), the vehicle-mounted device (for example, including a car windshield), or the splicing device.

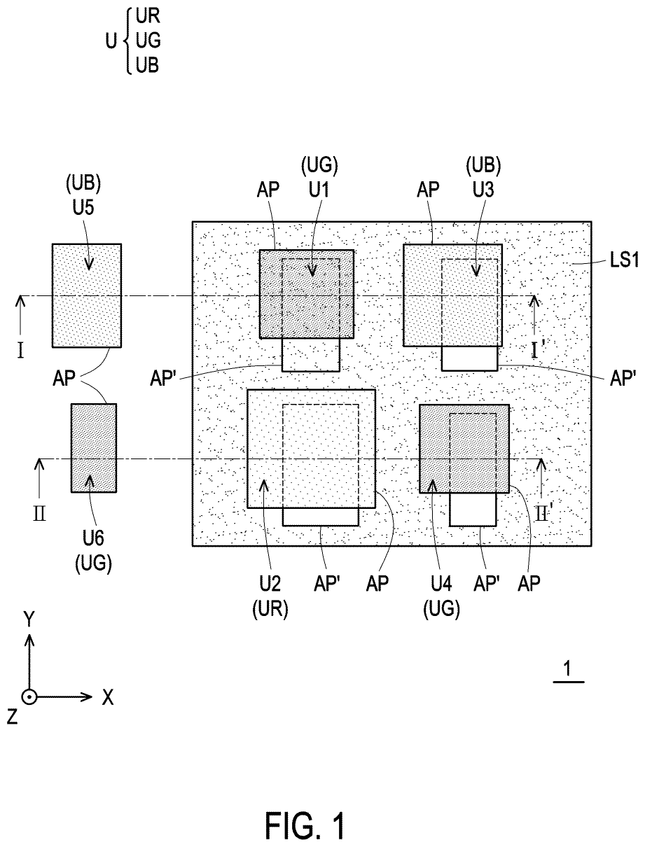

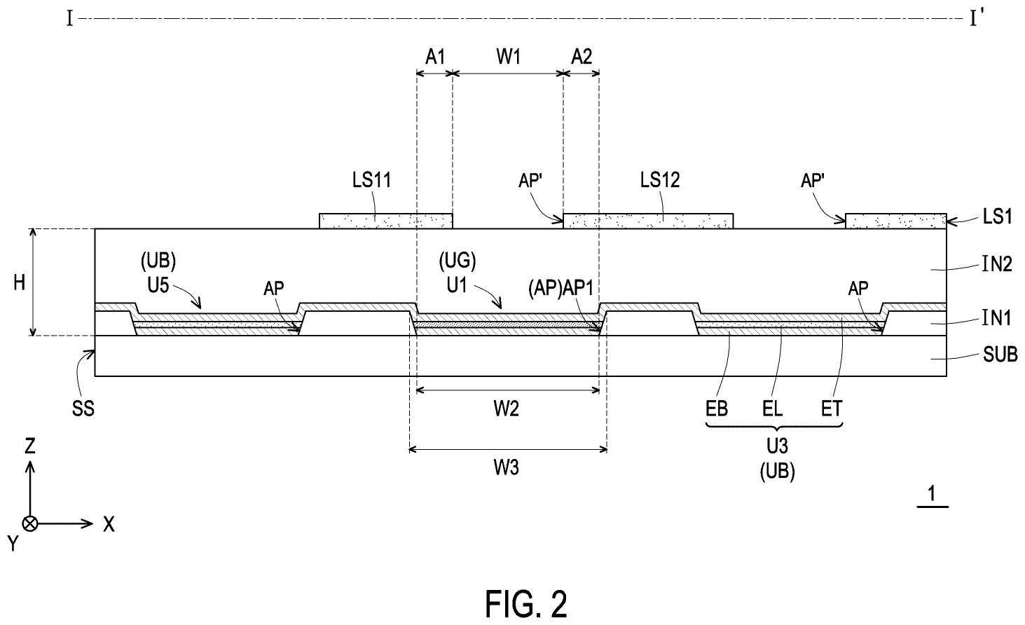

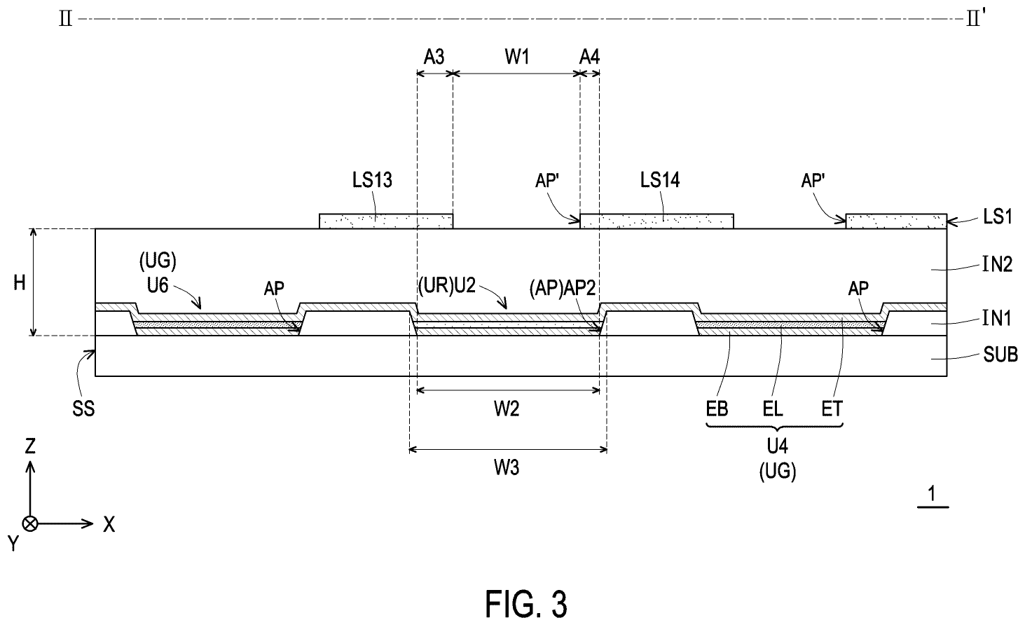

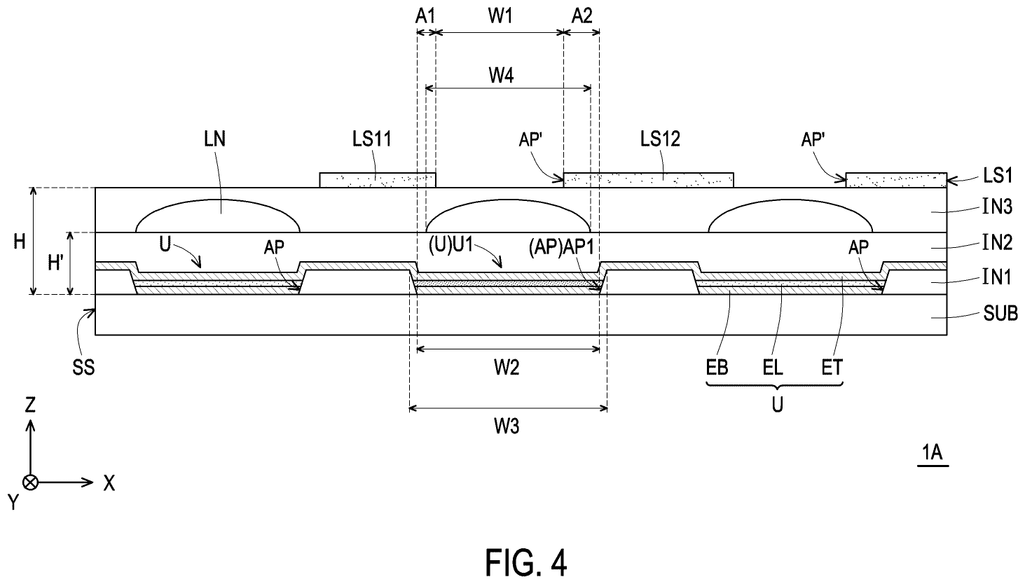

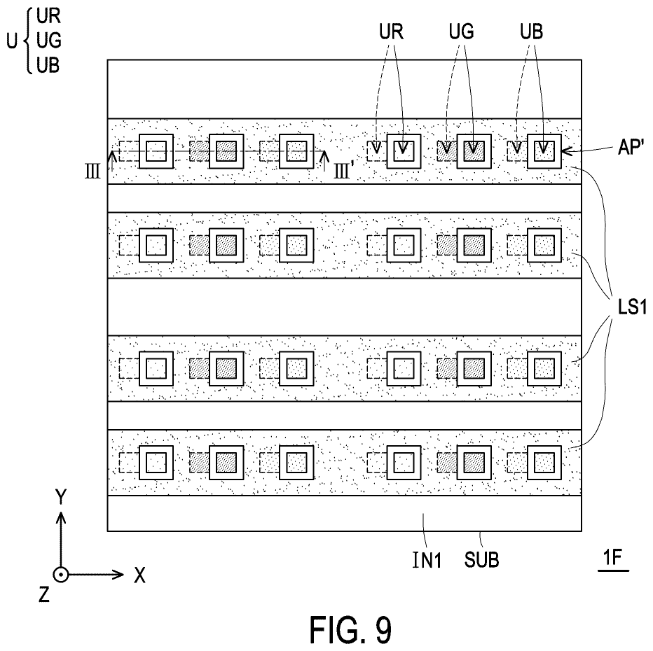

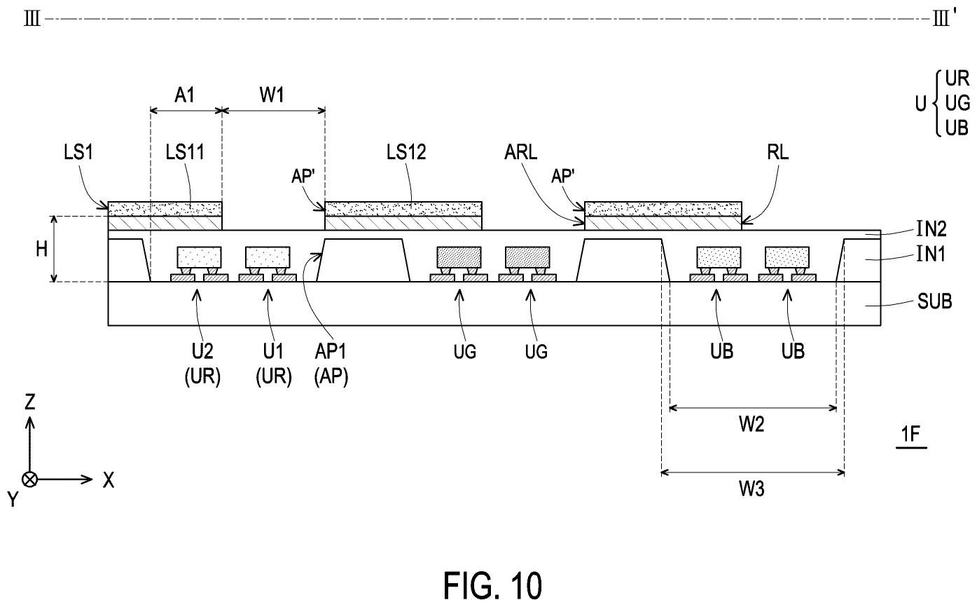

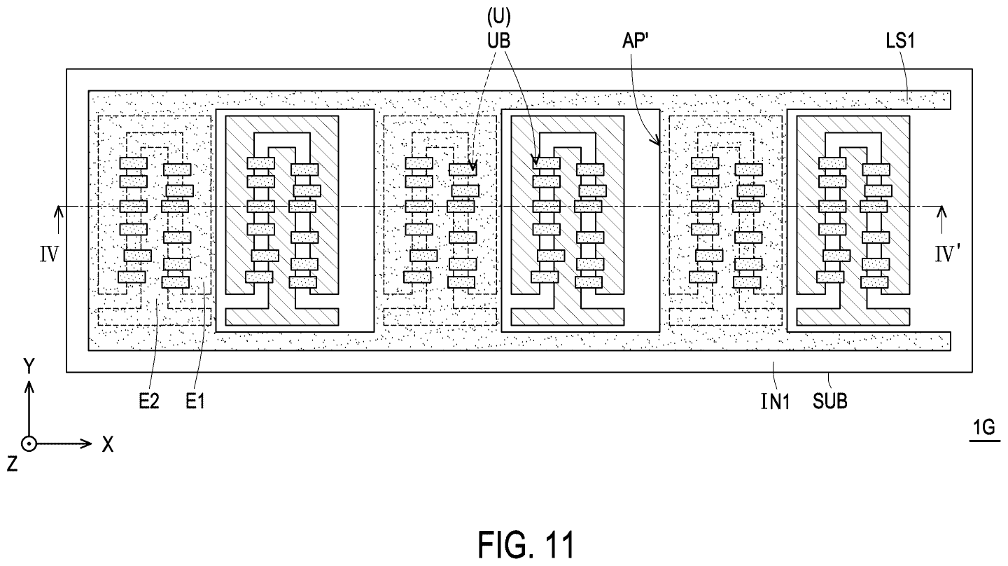

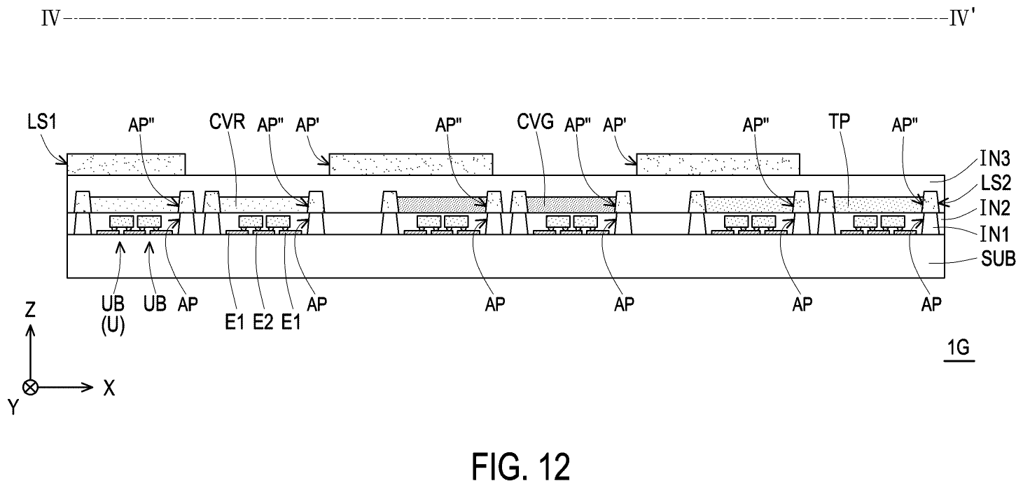

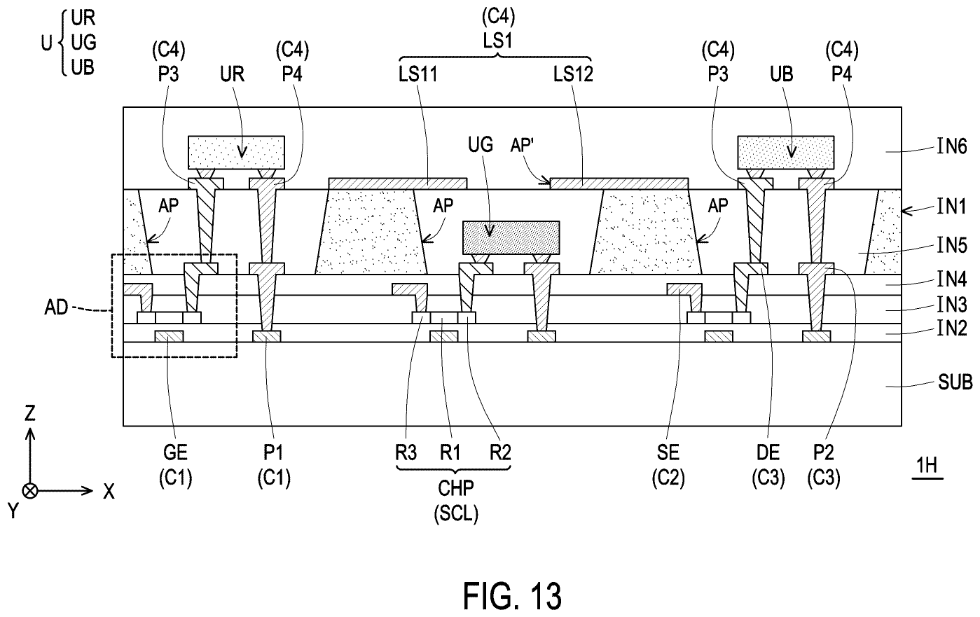

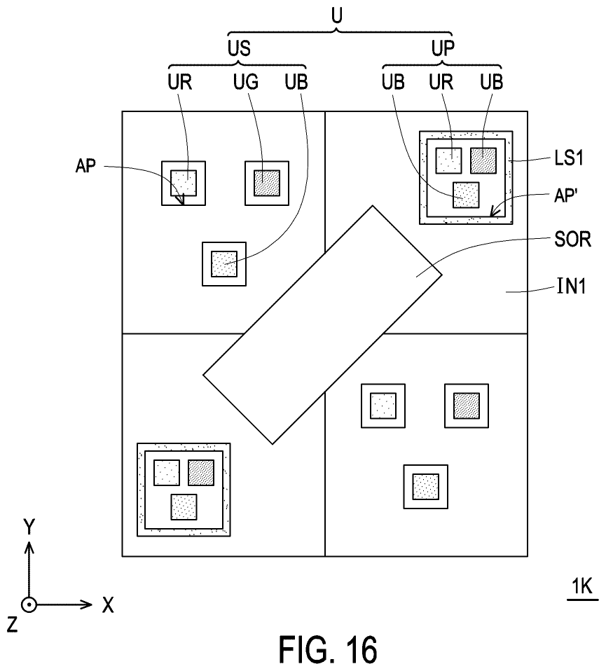

FIG. 1 is a partial top view of a light-emitting device according to a first embodiment of the disclosure. FIG. 2 and FIG. 3 are respectively schematic cross-sectional views viewing along a section line I-I′ and a section line II-II′ in FIG. 1. FIG. 4 to FIG. 8 are respectively partial cross-sectional schematic views of various light-emitting devices according to a second embodiment to a sixth embodiment of the disclosure. FIG. 9 is a partial top view of a light-emitting device according to a seventh embodiment of the disclosure. FIG. 10 is a schematic cross-sectional view viewing along a section line III-III′ in FIG. 9. FIG. 11 is a partial top view of a light-emitting device according to an eighth embodiment of the disclosure. FIG. 12 is a schematic cross-sectional view viewing along a section line IV-IV′ in FIG. 11. FIG. 13 to FIG. are respectively partial cross-sectional schematic views of various light-emitting devices according to a ninth embodiment to an eleventh embodiment of the disclosure. FIG. 16 is a partial top view of a light-emitting device according to a twelfth embodiment of the disclosure. It should be noted that features of several different embodiments of the disclosure may be replaced, reorganized, and mixed to complete other embodiments without departing from the spirit of the disclosure. Features in various embodiments may be mixed and matched as long as they do not violate the spirit of the invention or conflict with each other.

Referring to FIG. 1 to FIG. 3, a light-emitting device 1 may include a substrate SUB, an insulating layer IN1, a first light-emitting unit U1, and a first light-shielding layer LS1. The insulating layer IN1 is disposed on the substrate SUB and includes a first opening AP1. The first light-emitting unit U1 is disposed in the first opening AP1. The first light-shielding layer LS1 is disposed on the insulating layer IN1. In the cross-sectional view (for example, FIG. 2), the first light-shielding layer LS1 includes a first light-shielding portion LS11 and a second light-shielding portion LS12 adjacent to the first light-shielding portion LS11. A first overlapping area A1 of the first light-shielding portion LS11 is defined by a portion of the first light-shielding portion LS11 that overlaps the first opening AP1, a second overlapping area A2 of the second light-shielding portion LS12 is defined by a portion of the second light-shielding portion LS12 that overlaps the first opening AP1, and the first overlapping area A1 is different from the second overlapping area A2.

In detail, the substrate SUB may be a rigid substrate or a flexible substrate. A material of the substrate SUB includes, for example, glass, quartz, ceramics, sapphire or plastic, but the disclosure is not limited thereto. The plastic may include polycarbonate (PC), polyimide (PI), polypropylene (PP), polyethylene terephthalate (PET), and other suitable flexible materials or a combination of the aforementioned materials, but the disclosure is not limited thereto.

The insulating layer IN1 may also be referred to as a pixel definition layer, which may be used to provide an opening for accommodating the light-emitting unit. A material of the insulating layer IN1 includes, for example, an organic insulating material, an inorganic insulating material, or a combination thereof. The organic insulating material includes, for example, polymethylmethacrylate (PMMA), epoxy, acrylic-based resin, silicone, polyimide polymer, or a combination thereof, but the disclosure is not limited thereto. The inorganic insulating material includes, for example, silicon oxide or silicon nitride, but the disclosure is not limited thereto. In some embodiments, the material of the insulating layer IN1 may include an opaque material to reduce problems such as light interference and/or light mixing. The opaque material may include a white, gray or black organic polymer material, such as a black matrix, but the disclosure is not limited thereto.

The first light-emitting unit U1 may be used to provide a light beam. For example, the first light-emitting unit U1 may include a light-emitting diode (LED), an organic LED, a mini LED, a micro LED or a quantum dot LED.

In some embodiments, the insulating layer IN1 may include a plurality of openings AP, and the light-emitting device 1 may include a plurality of light-emitting units U. An arrangement relationship between the openings AP and the light-emitting units U may be one-to-one (as shown in FIG. 2 or FIG. 3) or one-to-many (as shown in FIG. 10 or FIG. 12). The plurality of light-emitting units U may include a plurality of LEDs, a plurality of organic LEDs, a plurality of mini LEDs, a plurality of micro LEDs or a plurality of quantum dot LEDs. The plurality of light-emitting units U may be arranged in an array in a direction X and a direction Y. The directions X and Y intersect each other, and a plane formed by the directions X and Y is parallel to a surface of the substrate SUB and perpendicular to a thickness direction of the substrate SUB (such as a direction Z). In some embodiments, the direction X and the direction Y are perpendicular to each other, but the disclosure is not limited thereto.

According to different requirements, the plurality of light-emitting units U may include multiple light-emitting units of different colors or multiple light-emitting units of a single color. For example, when the plurality of light-emitting units U serve as display pixels, the plurality of light-emitting units U may include a plurality of red light-emitting units UR (only one is schematically shown in FIG. 1), a plurality of green light-emitting units UG and a plurality of blue light-emitting units UB, but the disclosure is not limited thereto. On the other hand, when the plurality of light-emitting units U are used as backlights, the plurality of light-emitting units U may include a plurality of monochromatic light-emitting elements, such as a plurality of white light-emitting elements or a plurality of blue light-emitting elements, but the disclosure is not limited thereto.

Taking an organic light-emitting diode (OLED) as an example, as shown in FIG. 2 and FIG. 3, the light-emitting unit U may include a bottom electrode EB, a light-emitting layer EL and a top electrode ET. The bottom electrode EB is disposed on the substrate SUB and located at a bottom of the opening AP. The light-emitting layer EL is disposed on the bottom electrode EB and is at least partially located in the opening AP. The top electrode ET is disposed on the light-emitting layer EL and is at least partially located in the opening AP. In the specification, the opening AP is a space where the insulating layer IN1 is hollowed out. “The light-emitting unit U is disposed in the opening AP” means that at least a part of the light-emitting unit U falls in the opening AP, but is not limited to all of the light-emitting unit U falling in the opening AP. For example, under the framework of an OLED, as shown in FIG. 2 or FIG. 3, the top electrode ET may further extend to the insulating layer IN1, and a plurality of top electrodes ET of the plurality of light-emitting units U may be connected to each other, so that a part of the light-emitting unit U falls outside the opening AP.

The first light-shielding layer LS1 may be used to reflect or absorb the light beam, so that at least a part of the light beam cannot be transmitted directly forward. A material of the first light-shielding layer LS1 includes, for example, black matrix, metal or other opaque materials, but the disclosure is not limited thereto. In some embodiments, the first light-shielding layer LS1 may be indirectly disposed on the insulating layer IN1. Taking FIG. 2 and FIG. 3 as an example, the light-emitting device 1 may further include an insulating layer IN2, where the insulating layer IN2 is disposed on the plurality of top electrodes ET of the plurality of light-emitting units U, and provides a flat surface for carrying the first light-shielding layer LS1. A material of the insulating layer IN2 is, for example, a light-transmitting material, such as an organic insulating material, an inorganic insulating material or a combination thereof.

In some embodiments, as shown in FIG. 1, the first light-shielding layer LS1 may include a plurality of light-transmitting openings AP′, and each light-transmitting opening AP′ may overlap with the corresponding one or more light-emitting units U, so as to control a light emission angle of the light beam emitted from the light-emitting device 1. Taking FIG. 2 or FIG. 3 as an example, a required viewing angle may be achieved by controlling a vertical distance H between the substrate SUB and the first light-shielding layer LS1 and/or a relative size design of the light-transmitting opening AP′ and the opening AP. For example, when a width of the light-transmitting opening AP′ is W1, a minimum width of the opening AP is W2, and a maximum width of the opening AP is W3, a narrow viewing angle requirement may be met by making W1<W2. In some embodiments, 0.5*W2<W1<W2. In some embodiments, W1<W2<W3.

In some embodiments, when the vertical distance His 10 μm, the width W1 is, for example, less than 5 μm, so that the viewing angle is less than 30 degrees. In some embodiments, when a top width of the first opening AP1 (or the opening AP) is greater than a bottom width of the first opening AP1 (or the opening AP), the maximum width W3 of the first opening AP1 (or the opening AP) is measured at a position higher than the first light-emitting unit U1 (or the light-emitting unit U).

In some embodiments, an asymmetric viewing angle effect may be achieved by designing the light-transmitting opening AP′ of the first light-shielding layer LS1 to deviate from the opening AP of the insulating layer IN1. The design of deviation of the light-transmitting opening AP′ and the opening AP may include deviation of a center of the light-transmitting opening AP′ and a center of the opening AP in the direction X, so as to achieve the effect of asymmetric viewing angle in the direction X. The design of deviation of the light-transmitting opening AP′ and the opening AP may also include deviation of the center of the light-transmitting opening AP′ and the center of the opening AP in the direction Y, so as to achieve the effect of asymmetric viewing angle in the direction Y. The design of deviation of the light-transmitting opening AP′ and the opening AP may also include deviation of the center of the light-transmitting opening AP′ and the center of the opening AP in both of the direction X and the direction Y, so as to achieve the effect of asymmetric viewing angle in the direction X and the direction Y.

FIG. 2 schematically illustrates a design of deviation of the light-transmitting opening AP′ and the opening AP in the direction X. In FIG. 2, the light-transmitting opening AP′ is located in the middle of the first light-shielding portion LS11 and the second light-shielding portion LS12, and a range of the light-transmitting opening AP′ is defined by a side wall of the first light-shielding portion LS11 adjacent to the light-transmitting opening AP′ and a side wall of the second light-shielding portion LS12 adjacent to the light-transmitting opening AP′. In the case that the bottom width and the top width of the first opening AP1 are different, the overlapping area may be calculated uniformly by using the top of the first opening AP1 or the bottom of the first opening AP1. For example, the first overlapping area A1 of the first light-shielding portion LS11 may be defined by a complete overlapping portion of the first light-shielding portion LS11 and the bottom of the first opening AP1, and the second overlapping area A2 of the second light-shielding portion LS12 may be defined by a complete overlapping portion of the second light-shielding portion LS12 and the bottom of the first opening AP1. If the first light-shielding portion LS11 does not overlap with the bottom of the first opening AP1, the first overlapping area A1 is zero. Similarly, if the second light-shielding portion LS12 does not overlap with the bottom of the first opening AP1, the second overlapping area A2 is zero. In the case that the light-transmitting opening AP′ deviates from the opening AP, the first overlapping area A1 is different from the second overlapping area A2. In this way, a light emission angle (referring to an included angle between a light beam transmission direction and the direction Z) of the light beam emitted from a left side of the light-transmitting opening AP′ is different from a light emission angle of the light beam emitted from a right side of the light-transmitting opening AP′, so as to achieve the effect of asymmetric viewing angle.

Although the above-mentioned asymmetric viewing angle design is described by taking the green light-emitting unit UG as an example, it should be understood that other color light-emitting units (such as the red light-emitting unit UR and/or the blue light-emitting unit UB) may also adopt the above-mentioned asymmetric viewing angle design. For example, as shown in FIG. 3, the insulating layer IN1 may further include a second opening AP2, and the light-emitting device 1 may further include a second light-emitting unit U2 (for example, a red light-emitting unit UR), and the second light-emitting unit U2 is disposed on in the second opening AP2. In another cross-sectional view (as shown in FIG. 3), the first light-shielding layer LS1 further includes a third light-shielding portion LS13 and a fourth light-shielding portion LS14 adjacent to the third light-shielding portion LS13, where a third overlapping area A3 of the third light-shielding portion LS13 is defined by a portion of the third light-shielding portion LS13 that overlaps the second opening AP2, and ae fourth overlapping area A4 of the fourth light-shielding portion LS14 is defined by a portion of the fourth light-shielding portion LS14 that overlaps the second opening AP2, and the third overlapping area A3 is different from the fourth overlapping area A4. In some embodiments, although not shown, the blue light-emitting unit UB may also adopt the above-mentioned asymmetric viewing angle design, which will not be repeated.

When sizes of the light-emitting units of different colors are different (as shown in FIG. 1), deviation degrees of different light-transmitting openings AP′ may be different to achieve the effect of similar viewing angles of various colors. Taking FIG. 2 and FIG. 3 as an example, the first light-emitting unit U1 and the second light-emitting unit U2, for example, emit light of different colors, such as green light and red light. In some embodiments, a difference between the first overlapping area A1 and the second overlapping area A2 (for example, |A1-A2|) may be different from a difference between the third overlapping area A3 and the fourth overlapping area A4 (for example, |A3-A4|). In some embodiments, the first overlapping area A1 is different from the third overlapping area A3, and/or the second overlapping area A2 is different from the fourth overlapping area A4. In some embodiments, the first overlapping area A1 divided by the second overlapping area A2 may be different from the third overlapping area A3 divided by the fourth overlapping area A4.

In some embodiments, deviation directions of the plurality of light-transmitting openings AP′ may be the same or opposite. FIG. 2 and FIG. 3 illustrate structures in which the deviation directions of the plurality of light-transmitting openings AP′ are the same. Specifically, in FIG. 2 and FIG. 3, the substrate SUB includes a side SS, the first overlapping area A1 is larger than the second overlapping area A2, and the first overlapping area A1 is closer to the side SS than the second overlapping area A2. The overlapping area A3 is larger than the fourth overlapping area A4, and the third overlapping area A3 is closer to the side SS than the fourth overlapping area A4. In other words, the light-transmitting opening AP′ corresponding to the first light-emitting unit U1 and the light-transmitting opening AP′ corresponding to the second light-emitting unit U2 all deviate in a direction away from the side SS (such as the direction X), such that A1>A2, and A3>A4, but the disclosure is not limited thereto. In other embodiments, as shown in FIG. 4 and FIG. 3, the substrate SUB includes a side SS, the first overlapping area A1 may be less than the second overlapping area A2, and the first overlapping area A1 is closer to the side SS than the second overlapping area A2. The third overlapping area A3 is larger than the fourth overlapping area A4, and the third overlapping area A3 is closer to the side SS than the fourth overlapping area A4. In other words, the light-transmitting opening AP′ corresponding to the first light-emitting unit U1 may deviate toward the direction close to the side SS (for example, the direction opposite to the direction X), and the light-transmitting opening AP′ corresponding to the second light-emitting unit U2 may deviate in the direction away from the side SS (such as the direction X), so that A1<A2, and A3>A4. For example, in a car display situation, the side with a larger overlapping area may correspond to a driver side, thereby controlling the light beam emitted to the driver side and improving driving safety. A co-driver display (CDD) in a vehicle system may also adopt the asymmetric viewing angle design to provide an asymmetric light emission brightness. For example, in the case of left-hand drive, the light emission brightness on the right side may be greater than the light emission brightness on the left side, so as to reduce an influence of the light beam emitted by the CDD on the driver. A projection display in the vehicle system, such as a head-up display (HUD), may also adopt the asymmetric viewing angle design to provide asymmetric light emission brightness. For example, the light emission brightness on an upper side may be greater than the light emission brightness on a lower side, so that the light beam is concentrated on a projection screen (such as a windshield) to reduce the influence of the light beam emitted by the projection display on the driver.

Referring back to FIG. 1, in some embodiments, the light-emitting device 1 may include a narrow viewing angle mode and a wide viewing angle mode. When the light-emitting device 1 is in the narrow viewing angle mode, the first light-emitting unit U1 and the second light-emitting unit U2 are turned on, and when the light-emitting device 1 is in the wide viewing angle mode, the first light-emitting unit U1 and the second light-emitting unit U2 are turned off. In detail, when the light-emitting device 1 is in the narrow viewing angle mode, it may have a narrower viewing angle than the light-emitting device 1 in the wide viewing angle mode, i.e., a half-maximum width angle (a half-decay angle) range of the brightness of the light-emitting device 1 in the narrow viewing angle mode is narrower than the half-maximum wide angle range of the brightness of the light-emitting device 1 in the wide viewing angle mode, so that a display image cannot be observed at some viewing angles, for example, the display image may be observed at a front viewing angle, but cannot be observed at a side viewing angle. The side viewing angle is, for example, more than 15 degrees, more than 30 degrees, an angle corresponding to a driving line of sight, or an angle corresponding to any object in the car that may cause glare. When the light-emitting unit is turned on, it means that the light beam emitted by the light-emitting unit may be observed by a user, or a brightness that may be sensed by a photosensitive element is greater than 0. When the light-emitting unit is turned off, it means that the light beam emitted by the light-emitting unit cannot be observed by the user, or the brightness that is detected by the photosensitive element approaches 0 or the photosensitive element cannot detect it.

In some embodiments, a part of the plurality of light-emitting units U may be used as narrow viewing angle light-emitting units, and the other part of the plurality of light-emitting units U may be used as wide viewing angle light-emitting units. The narrow viewing angle light-emitting unit is turned on when the light-emitting device 1 is in the narrow viewing angle mode, and the narrow viewing angle light-emitting unit is turned off or turned on when the light-emitting device 1 is in the wide viewing angle mode. The first light-emitting unit U1, the second light-emitting unit U2, the third light-emitting unit U3 and the fourth light-emitting unit U4 in FIG. 1 are, for example, used as narrow viewing angle light-emitting units. On the other hand, the wide viewing angle light-emitting unit is turned off when the light-emitting device 1 is in the narrow viewing angle mode, and the narrow viewing angle light-emitting unit is turned on when the light-emitting device 1 is in the wide viewing angle mode. The fifth light-emitting unit U5 and the sixth light-emitting unit U6 in FIG. 1 are, for example, used as wide viewing angle light-emitting units.

In some embodiments, when the light-emitting device 1 is in the wide viewing angle mode, at least a part of the narrow viewing angle light-emitting units may be turned on, for example, a number and/or brightness (or gray scales) of the turned-on narrow viewing angle light-emitting units may be controlled, and the brightness (or gray scales) of the turned-on narrow viewing angle light-emitting units may be different. For example, a brightness of the first light-emitting unit U1 may be greater than a brightness of the second light-emitting unit U2. In some embodiments, when the light-emitting device 1 is in the narrow viewing angle mode, at least a part of the narrow viewing angle light-emitting units may also be turned on, and the brightness (or gray scales) of the turned-on narrow viewing angle light-emitting units may be different, for example, the brightness of the first light-emitting unit U1 may be less than the brightness of the second light-emitting unit U2. In some embodiments, switching between the wide viewing angle mode and the narrow viewing angle mode may include turning on and off the plurality of light-emitting units U, or may include gradual switching of the plurality of light-emitting units U (for example, controlling the number and/or brightness (or gray scales) of the turned-on narrow viewing angle light-emitting units).

The narrow viewing angle light-emitting unit is overlapped with the light-transmitting opening AP′ of the first light-shielding layer LS1, and through the deviation design of the light-transmitting opening AP′, the asymmetric viewing angle effect may be achieved. In some embodiments, the plurality of narrow viewing angle light-emitting units may be arranged in an array in the direction X and the direction Y. The array may include a plurality of straight columns, and the plurality of narrow viewing angle light-emitting units in each straight column are arranged along the direction Y, and the plurality of straight columns are arranged along the direction X, where the plurality of light-transmitting openings AP′ corresponding to the plurality of narrow viewing angle light-emitting units in an odd number of straight column may be set to the left, and the plurality of light-transmitting openings AP′ corresponding to the plurality of narrow viewing angle light-emitting units in an even number of straight column may be set to the right to provide a dual view effect.

Since a human eye is more sensitive to red light, when the light-emitting device 1 is used in a vehicle-mounted device, the red light-emitting units in the light-emitting device 1 may adopt the aforementioned asymmetric viewing angle design to reduce the interference of red light to the driver.

In some embodiments, as shown in a light-emitting device 1A of FIG. 4, the light-emitting device 1A may further include a plurality of lens elements LN. The plurality of lens elements LN are respectively disposed above the plurality of light-emitting units U to increase light-emitting efficiency. In some embodiments, a width W4 of the lens element LN in the direction X is, for example, greater than the width W1 of the light-transmitting opening AP′ in the direction X, so as to improve a light converging effect of the lens element LN. Materials of the plurality of lens elements LN may include organic insulating materials, inorganic insulating materials, or combinations thereof. A cross-sectional shape of the lens element LN may be a semicircle. The semicircle means a part of a circle, and is not limited to a half of the circle. A top view shape of the lens element LN may be circular or strip-shaped. Taking FIG. 4 as an example, the strip-shaped lens element LN, for example, extends along the direction Y.

In some embodiments, the vertical distance H between the substrate SUB and the first light-shielding layer LS1 may be greater than a vertical distance H′ between the substrate SUB and the plurality of lens elements LN, so as to improve a light converging effect of the lens elements LN and/or improve the light-shielding effect of the first light-shielding layer LS1. For example, the plurality of lens elements LN may be disposed on the insulating layer IN2 and overlapped with the plurality of light-emitting units U in the direction Z. In addition, the light-emitting device 1A may further include an insulating layer IN3. The insulating layer IN3 is disposed on the insulating layer IN2 and the plurality of lens elements LN, and the first light-shielding layer LS1 may be disposed on the insulating layer IN3. A material of the insulating layer IN3 may refer to the material of the insulating layer IN2, while a material of the plurality of lens elements LN is different from the materials of the insulating layer IN2 and the insulating layer IN3. For example, the plurality of lens elements LN may adopt materials with a higher refractive index than that of the insulating layer IN2 and the insulating layer IN3 to provide the light converging effect.

In some embodiments, the lens element LN and the corresponding light-emitting unit U (or the corresponding opening AP) may adopt a center alignment design (referring to the left side of FIG. 4). In some embodiments, the lens element LN and the corresponding light-emitting unit U (or the corresponding opening AP) may adopt a center deviation design (referring to the right side of FIG. 4), and the light-transmitting opening AP′ of the first light-shielding layer LS1 and the corresponding light-emitting unit U (or the corresponding opening AP) may also adopt the center deviation design, where a deviation direction of the lens element LN and a deviation direction of the light-transmitting opening AP′ may be the same or opposite. Taking the right side of FIG. 4 as an example, a center of the light-transmitting opening AP′ of the first light-shielding layer LS1 may deviate from a center of the light-emitting unit U below the light-transmitting opening AP′ along the direction X, and a center of the lens element LN may deviate from the center of the light-emitting unit U below the lens element LN in the opposite direction of the direction X, but the disclosure is not limited thereto.

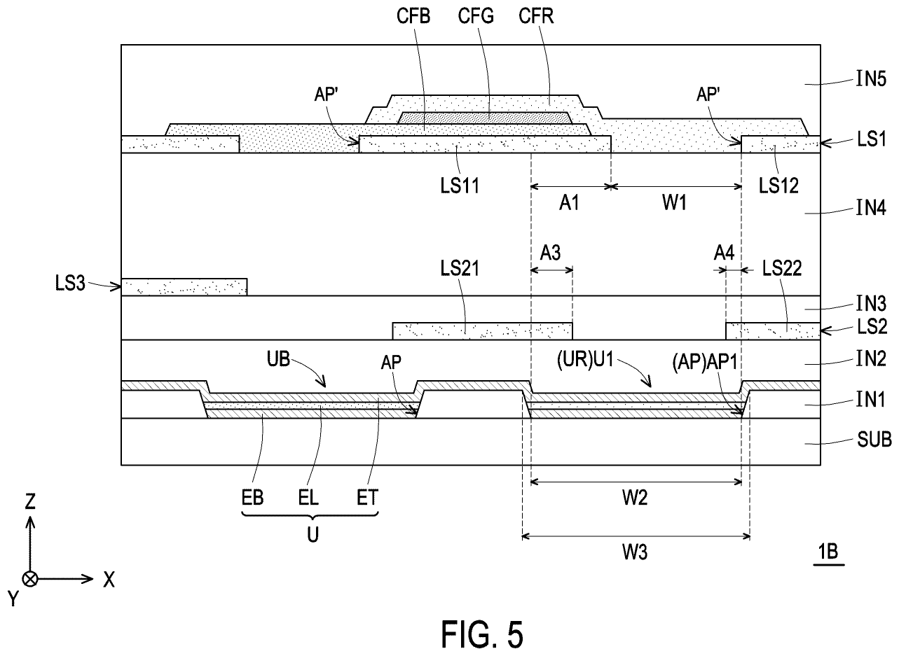

In some embodiments, as shown in a light-emitting device 1B of FIG. 5, the asymmetric viewing angle effect may be achieved through a plurality of light-shielding layers of different levels. For example, the light-emitting device 1B may further include a second light-shielding layer LS2. The second light-shielding layer LS2 is disposed between the insulating layer IN1 and the first light-shielding layer LS1, and in a cross-sectional view, the second light-shielding layer LS2 includes a third light-shielding portion LS21 and a fourth light-shielding portion LS22 adjacent to the third light-shielding portion LS21. A third overlapping area A3 of the third light-shielding portion LS21 is defined by a portion of the third light-shielding portion LS21 that overlaps the first opening AP1, a fourth overlapping area A4 of the fourth light-shielding portion LS22 is defined by a portion of the fourth light-shielding portion LS22 that overlaps the first opening AP1, and the third overlapping area A3 is different from the fourth overlapping area A4.

In some embodiments, the second light-shielding layer LS2 is disposed on the insulating layer IN2. A material of the second light-shielding layer LS2 may refer to the material of the first light-shielding layer LS2, which will not be repeated. The light-emitting device 1B may further include an insulating layer IN3. The insulating layer IN3 is disposed on the insulating layer IN2 and the second light-shielding layer LS2. A material of the insulating layer IN3 may refer to the material of the insulating layer IN2, which will not be repeated.

In some embodiments, the light-emitting device 1B may also include a third light-shielding layer LS3. The third light-shielding layer LS3 is disposed on the insulating layer IN3. A material of the third light-shielding layer LS3 may refer to the material of the first light-shielding layer LS2, which will not be repeated. The light-emitting device 1B may also include an insulating layer IN4. The insulating layer IN4 is disposed on the insulating layer IN3 and the third light-shielding layer LS3, and the first light-shielding layer LS1 is disposed on the insulating layer IN4. A material of insulating layer IN4 may refer to the material of the insulating layer IN2, which will not be repeated.

In FIG. 5, the third light-shielding layer LS3 partially overlaps one of the light-emitting units U in the direction Z, and the third light-shielding portion LS21 also partially overlaps the one of the light-emitting units U. Through the design that the light-shielding layers on opposite sides (such as the left and right sides) of the light-emitting unit U are arranged at different levels, the asymmetric viewing angle effect may also be achieved.

In some embodiments, the light-emitting device 1B may further include a light conversion layer (such as a red filter layer CFR, a green filter layer CFG, and a blue filter layer CFB). The light conversion layer is disposed on the substrate SUB, where at least a part of the light conversion layer is disposed between the first light-shielding portion LS11 and the second light-shielding portion LS12. Taking FIG. 5 as an example, the blue filter layer CFB may be disposed in one of the light-transmitting openings AP′ and extend to the first light-shielding portion LS11. The green filter layer CFG may be disposed on the blue filter layer CFB located on the first light-shielding part LS11. The red filter layer CFR may be disposed on the green filter layer CFG and extend to the other light-transmitting opening AP′.

By stacking the red filter layer CFR, the green filter layer CFG, and the blue filter layer CFB on each other, stray light may be absorbed to improve color purity or achieve an anti-reflective effect. In some embodiments, the plurality of filter layers disposed on the first light-shielding portion LS11 may be arranged in different orders.

In some embodiments, the light-emitting device 1B may further include an insulating layer IN5. The insulating layer IN5 is disposed on the light conversion layer and the first light-shielding layer LS1. A material of the insulating layer IN5 may refer to the material of the insulating layer IN2, which will not be repeated here.

Although FIG. 5 shows that the second light-shielding portion LS12 is aligned with a bottom edge of the first opening AP1, i.e., the second overlapping area A2 is equal to zero, the disclosure is not limited thereto. In other embodiments, although not shown, the second overlapping area A2 may be greater than zero. In other embodiments, the first overlapping area A1, the third overlapping area A3, and/or the fourth overlapping area A4 may be equal to zero.

In other embodiments, the plurality of light-emitting units U may be other types of light-emitting units. In other embodiments, the light conversion layer (such as the red filter layer CFR, the green filter layer CFG, and the blue filter layer CFB) may be disposed on another substrate (not shown), and the light conversion layer may be bonded to the substrate SUB through an adhesive layer (not shown). The adhesive layer may include, for example, optical clear adhesive (OCA) or optical clear resin (OCR), but the disclosure is not limited thereto.

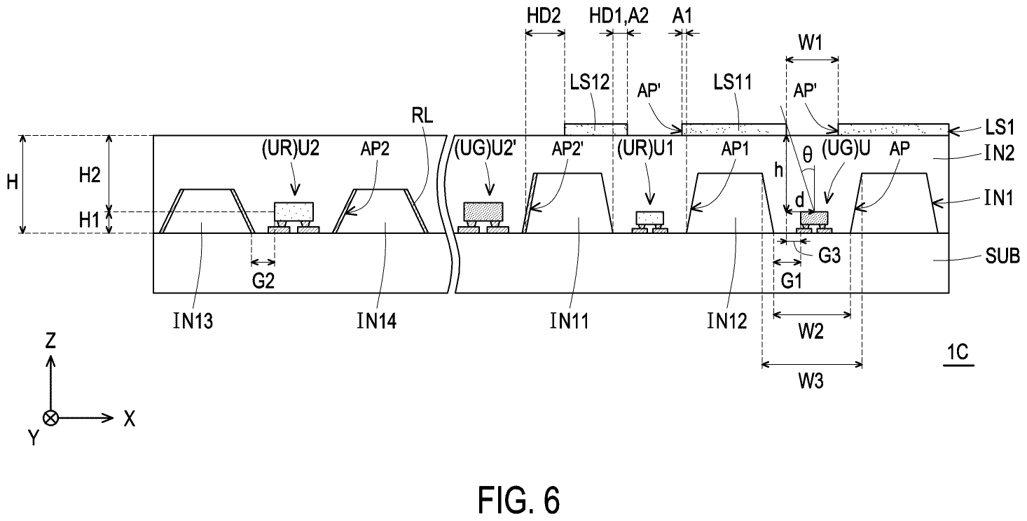

In some embodiments, as shown in a light-emitting device 1C of FIG. 6, the plurality of light-emitting units U are, for example, a plurality of micro LEDs, and the plurality of light-emitting units U are, for example, arranged on the substrate SUB through flip chip bonding or wire bonding. In some embodiments, heights of a light-emitting layer (not shown) in the micro LED and the first light-shielding layer LS1 may be similar. For example, if a distance between the light-emitting layer in the micro LED and the substrate SUB is H1, and a distance between the light-emitting layer in the micro LED and the first light-shielding layer LS1 is H2, the light-emitting device 1C may satisfy 0.5< (H1/H2)<5.

In some embodiments, the insulating layer IN1 may further include a second opening AP2, and the light-emitting device 1C may further include a second light-emitting unit U2. The second light-emitting unit U2 is disposed in the second opening AP2. The light-emitting device 1C includes a narrow viewing angle mode and a wide viewing angle mode. When the light-emitting device 1C is in the narrow viewing angle mode, the first light-emitting unit U1 is turned on and the second light-emitting unit U2 is turned off. When the light-emitting device 1C is in the wide viewing angle mode, the first light-emitting unit U1 is turned off and the second light-emitting unit U2 is turned on. In other words, the first light-emitting unit U1 and the second light-emitting unit U2 are respectively a narrow viewing angle light-emitting unit and a wide viewing angle light-emitting unit. FIG. 6 schematically illustrates four light-emitting units, where the two light-emitting units on the left are, for example, wide viewing angle light-emitting units, and the two light-emitting units on the right are, for example, narrow viewing angle light-emitting units. In some embodiments, the narrow viewing angle light-emitting units and the wide viewing angle light-emitting units may have different/same sizes and/or light-emitting angles. As shown in FIG. 6, a size of the wide viewing angle light-emitting unit may be larger than a size of the narrow viewing angle light-emitting unit, but the disclosure is not limited thereto. In other embodiments that are not shown, the size of the wide viewing angle light-emitting unit may be equal to the size of the narrow viewing angle light-emitting unit.

In some embodiments, if a gap between the narrow viewing angle light-emitting unit and a side wall surface of the corresponding opening AP of the insulating layer IN1 is G1, a gap between the wide viewing angle light-emitting unit and the side wall surface of the corresponding opening AP of the insulating layer IN1 is G2, and a gap between the narrow viewing angle light-emitting unit and a side wall surface of the corresponding light-transmitting opening AP′ of the first light-shielding layer LS1 is G3, then the light-emitting device 1C may satisfy G1/G2, and G1G3.

In some embodiments, when the light-emitting device 1C is in the narrow viewing angle mode, the viewing angle of the light-emitting device 1C (such as a light emission angle θ) is determined by a gap d between a center of the light-emitting unit U and the side wall surface of the corresponding light-transmitting opening AP′ and a distance h from the light-emitting unit U to the first light-shielding layer LS1. Specifically, tanθ=d/h, where the larger h is, the smaller θ is, and the larger d is, the larger θ is. Taking a current PPI of an automotive device of about 150-300 as an example, a pixel size is about 13 μm. If h is 10 μm, then G3 needs to be at least larger than 3 μm, so that 0 is 45 degrees; and G3 needs to be at least larger than 7.22 μm, so that 0 is 30 degrees.

In some embodiments, the insulating layer IN1 may include a plurality of insulating portions, and the insulating portion adjacent to the wide viewing angle light-emitting unit and the insulating portion adjacent to the narrow viewing angle light-emitting unit may adopt different designs. For example, a reflectivity of the insulating portion adjacent to the wide viewing angle light-emitting unit may be greater than a reflectivity of the insulating portion adjacent to the narrow viewing angle light-emitting unit, and/or the side wall of the insulating portion adjacent to the narrow viewing angle light-emitting unit may be steeper than the side wall of the insulating portion adjacent to the wide viewing angle light-emitting unit. As shown in FIG. 6, in a cross-sectional view (shown as a right half of an omission line in FIG. 6), the insulating layer IN1 may include a first insulating portion IN11 and a second insulating portion IN12 adjacent to the first insulating portion IN11, and the first light-emitting unit U1 is disposed between the first insulating portion IN11 and the second insulating portion IN12. In another cross-sectional view (shown as a left half of the omission line in FIG. 6), the insulating layer IN1 may include a third insulating portion IN13 and a fourth insulating portion IN14 adjacent to the third insulating portion IN13, and the second light-emitting unit U2 is disposed between the third insulating portion IN13 and the fourth insulating portion IN14, where a reflectivity of at least one of the third insulating portion IN13 and the fourth insulating portion IN14 may be greater than a reflectivity of at least one of the first insulating portion IN11 and the second insulating portion IN12. The above reflectivity design may be achieved through a selection of materials and/or a setting of reflective layers, and the reflectivity is calculated by dividing a reflection brightness by an incident brightness. For example, in some embodiments, the light-emitting device 1C may further include a reflective layer RL. In the another cross-sectional view (shown as the left half of the omission line in FIG. 6), the insulating layer IN2 includes a third insulating portion IN13 and a fourth insulating portion IN14 adjacent to the third insulating portion IN13, the second light-emitting unit U2 is disposed between the third insulating portion IN13 and the fourth insulating portion IN14, and the reflective layer RL is disposed on a side wall of at least one of the third insulating portion IN13 and the fourth insulating portion IN14. A material of the reflective layer RL may include metal or other reflective materials. FIG. 6 schematically illustrates that the reflective layer RL is disposed on the two side walls of the third insulating portion IN13, the two side walls of the fourth insulating portion IN14, and a side wall of the first insulating portion IN11 away from the first light-emitting unit U1, but the disclosure is not limited thereto. In other embodiments, although not shown in FIG. 6, the reflective layer RL may also be disposed at the bottom of the first light-shielding layer. In addition, a slope of at least one of the side walls of the first insulating portion IN11 and the second insulating portion IN12 may be greater than a slope of at least one of the side walls of the third insulating portion IN13 and the fourth insulating portion IN14.

In some embodiments, at a junction of the narrow viewing angle light-emitting unit and the wide viewing angle light-emitting unit, for example, with reference to a location of the first insulating portion IN11, a relative setting relationship between the second light-shielding portion LS12 and the first insulating portion IN11 may be designed to maintain the narrow angle of view of the narrow viewing angle light-emitting unit (such as the first light-emitting unit U1 in FIG. 6) while reducing the influence of the second light-shielding portion LS12 on the light emission angle of the wide viewing angle light-emitting unit. As shown in FIG. 6, the light-emitting device 1C further includes a second light-emitting unit U2′, and the second light-emitting unit U2′ is disposed in the second opening AP2′, where the first light-emitting unit U1 and the second light-emitting unit U2′ are respectively a narrow viewing angle light-emitting unit and a wide viewing angle light-emitting unit. For example, when the light-emitting device 1C is in the narrow viewing angle mode, the first light-emitting unit U1 is turned on and the second light-emitting unit U2′ is turned off, and when the light-emitting device 1C is in the wide viewing angle mode, the first light-emitting unit U1 is turned off and the second light-emitting unit U2′ is turned on. The first insulating portion IN11 of the insulating layer IN1 is between the first light-emitting unit U1 and the second light-emitting unit U2 and at least partially overlaps the second light-shielding portion LS12, and in the cross-sectional view (shown as a right half of the omission line in FIG. 6), the third overlapping area of the second light-shielding portion LS12 is defined by the portion of the second light-shielding portion LS12 that overlaps the second opening AP2′, and the third overlapping area is different from the second overlapping area A2, for example, the third overlapping area may be less than the second overlapping area A2. In FIG. 6, the second light-shielding portion LS12 does not overlap the second opening AP2′, so that the third overlapping area is zero. By arranging the second light-shielding portion LS12 close to the narrow viewing angle light-emitting unit (the first light-emitting unit U1 in FIG. 6) and away from the wide viewing angle light-emitting unit (the second light-emitting unit U2′ in FIG. 6), the influence of the light-shielding portion LS12 on the light emission angle of the wide viewing angle light-emitting unit may be reduced. For example, in FIG. 6, a first distance HD1 between the side wall of the second light-shielding portion LS12 close to the first opening AP1 and the side wall of the first insulating portion IN11 close to the first opening AP1 is different from a second distance HD2 between the side wall of the second light-shielding portion LS12 away from the first opening AP1 and the side wall of the first insulating portion IN11 away from the first opening AP1. In some embodiments, the first distance HD1 is, for example, less than the second distance HD2.

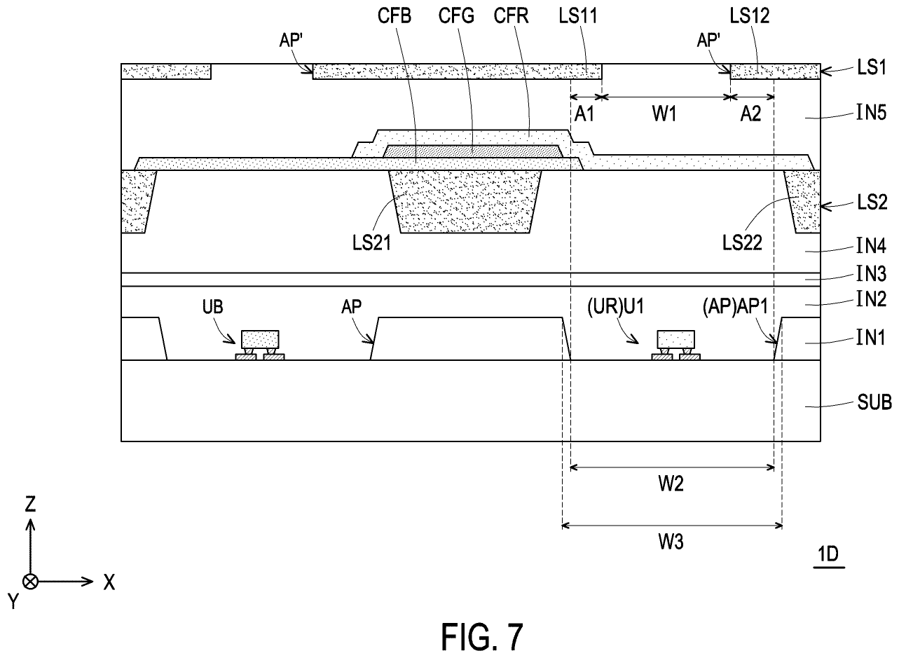

Referring to FIG. 7, main differences between a light-emitting device 1D and the light-emitting device 1B of FIG. 5 are described below. In the light-emitting device 1D, the plurality of light-emitting units (including the red light-emitting unit UR and the blue light-emitting unit UB) are, for example, a plurality of micro LEDs, and the plurality of light-emitting units U are, for example, arranged on the substrate SUB through flip chip bonding or wire bonding. In addition, the insulating layer IN1 may be made of a light-absorbing organic material. In addition, the second light-shielding layer LS2 is embedded in the insulating layer IN4, where the third light-shielding portion LS21 and the fourth light-shielding portion LS22 of the second light-shielding layer LS2 do not overlap the first opening AP1, so that the third overlapping area A3 (refer to FIG. 5) and the fourth overlapping area A4 are all zero. Furthermore, the light-emitting device 1D further includes an insulating layer IN5. The insulating layer IN5 is disposed between the light conversion layer (such as the red filter layer CFR, the green filter layer CFG, and the blue filter layer CFB) and the first light-shielding layer LS1, and the first light-shielding layer LS1 is embedded in the insulating layer IN5. A material of the insulating layer IN5 may refer to the material of the insulating layer IN2, which will not be repeated here.

By digging holes in the insulating layer IN4 and filling a light-absorbing material of the second light-shielding layer LS2, it helps to absorb side light leakage. In some embodiments, although not shown, the plurality of light-shielding portions (including the third light-shielding portion LS21 and the fourth light-shielding portion LS22) of the second light-shielding layer LS2 may penetrate through the insulating layer IN4, the insulating layer IN3 and the insulating layer IN2 to connect with the insulating layer IN1, so as to improve the effect of absorbing side light leakage.

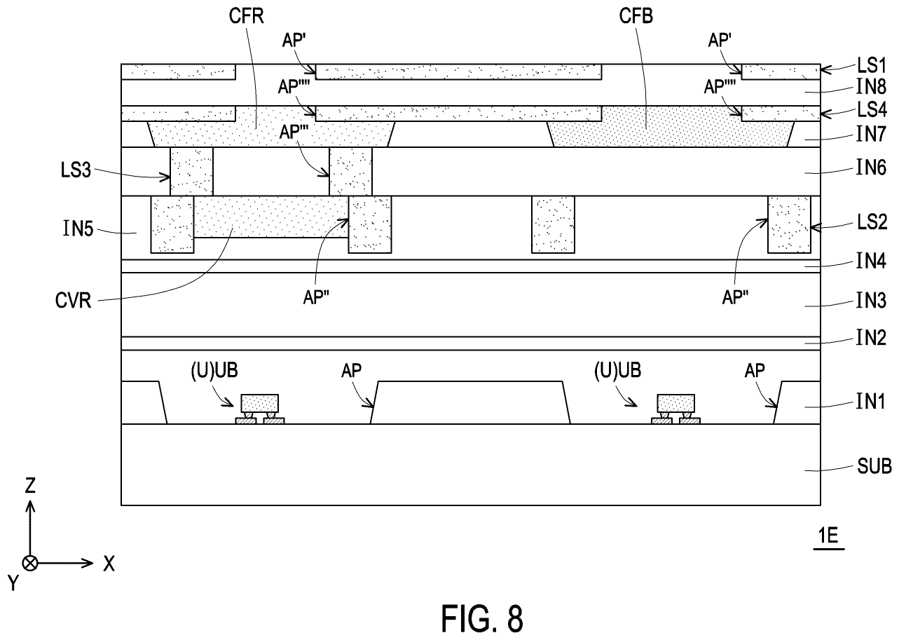

Referring to FIG. 8, main differences between a light-emitting device 1E and the light-emitting device 1D of FIG. 7 are described below. In the light-emitting device 1E, the plurality of light-emitting units U are, for example, all blue light-emitting units UB. A material of the insulating layer IN2 may include organic insulating materials, inorganic insulating materials, combinations thereof, optical transparent glue or optical transparent resin. The second light-shielding layer LS2 is embedded in the insulating layer IN5, and the light-emitting device 1E further includes a light conversion layer CVR. The light conversion layer CVR is disposed in the light-transmitting opening AP″ of the second light-shielding layer LS2, and a material of the light conversion layer CVR may include fluorescence, phosphor, quantum dots or other suitable light wavelength conversion materials. In the embodiment, the light conversion layer CVR overlaps with the red filter layer CFR. Therefore, the light conversion layer CVR is, for example, a light wavelength conversion material that converts blue light into red light, but the disclosure is not limited thereto. The light-emitting device 1E further includes an insulating layer IN6 and a third light-shielding layer LS3. The insulating layer IN6 is disposed on the insulating layer IN5 and the second light-shielding layer LS2, and the third light-shielding layer LS3 is embedded in the insulating layer IN6, where a light-transmitting opening AP″ of the third light-shielding layer LS3 overlaps the light-transmitting opening AP″ in the direction Z. The light-emitting device 1E further includes an insulating layer IN7 and a fourth light-shielding layer LS4. The insulating layer IN7 is disposed on the insulating layer IN6 and the third light-shielding layer LS3, and the red filter layer CFR, the blue filter layer CFB, and the fourth light-shielding layer LS4 are embedded in the insulating layer IN7, where a light-transmitting opening AP″” of the fourth light-shielding layer LS4 overlaps the light-transmitting opening AP″ in the direction Z, and the red filter layer CFR and the blue filter layer CFB are respectively disposed in the light-transmitting opening AP′ “. The light-emitting device 1E further includes an insulating layer IN8. The insulating layer IN8 is disposed on the insulating layer IN7, the red filter layer CFR, the blue filter layer CFB, and the fourth light-shielding layer LS4, and the first light-shielding layer LS1 is embedded in the insulating layer IN8. Materials of the insulating layer IN6, the insulating layer IN7 and the insulating layer IN8 may include organic insulating materials, inorganic insulating materials or combinations thereof. Materials of the third light-shielding layer LS3 and the fourth light-shielding layer LS4 may refer to the material of the first light-shielding layer LS1, which will not be repeated here.

By providing multiple light-shielding layers, it avails absorbing stray light (such as stray light from the light conversion layer CVR) or side leaked light, thereby improving color purity or display quality.

Referring to FIG. 9 and FIG. 10, main differences between a light-emitting device 1F and the light-emitting device 1 of FIG. 1 and FIG. 2 are described below. In the light-emitting device 1F, the plurality of light-emitting units U are, for example, a plurality of micro LEDs, and the plurality of light-emitting units U are, for example, disposed on the substrate SUB through flip chip bonding or wire bonding. In addition, the light-emitting device 1F further includes a second light-emitting unit U2, and the second light-emitting unit U2 is disposed in the first opening AP1. In detail, in the light-emitting device 1F, each opening AP in the insulating layer IN1 is, for example, provided with two light-emitting units U of the same color, one of the two light-emitting units U of the same color serves as a wide viewing angle light-emitting unit, and the other one of the two light-emitting units U of the same color serves as a narrow viewing angle light-emitting unit, where the light-transmitting opening AP′ overlapped by each opening AP, for example, overlaps the wide viewing angle light-emitting unit and does not overlap the narrow viewing angle light-emitting unit, which means that the narrow viewing angle light-emitting unit is shielded by the first light-shielding layer LS1. Taking FIG. 10 as an example, the light-transmitting opening AP′ between the first light-shielding portion LS11 and the second light-shielding portion LS12 overlaps the first light-emitting unit U1 and does not overlap the second light-emitting unit U2. Under such framework, the first light-emitting unit U1 and the second light-emitting unit U2, for example, respectively serve as a wide viewing angle light-emitting unit and a narrow viewing angle light-emitting unit.

In some embodiments, the light-emitting device IF may further include a reflective layer RL. The reflective layer RL is disposed between the insulating layer IN2 and the first light-shielding layer LS1, and the reflective layer RL may have a plurality of light-transmitting openings ARL. The plurality of light-transmitting openings ARL overlap with the plurality of light-transmitting openings AP′ in the direction Z, so as to reduce shielding of the light emitted by the light-emitting units.

In FIG. 10, the second light-shielding portion LS12 and the first opening AP1 do not overlap in the direction Z, which means that the second overlapping area A2 (referring to FIG. 2) is zero, but the disclosure is not limited thereto. In other embodiments, although not shown, the second overlapping area A2 may be non-zero.

In FIG. 10, the two light-emitting units disposed in the same opening AP are electrically insulated from each other and separated from each other without being connected, but the disclosure is not limited thereto. In other embodiments, although not shown, the two light-emitting units disposed in the same opening AP may be electrically isolated from each other and connected to each other, for example, connected via a growth substrate, so as to save a number of times of transfers.

In other embodiments, although not shown, the two micro LEDs disposed in the same opening AP may be replaced by two organic LEDs, and the two organic LEDs are respectively located in two openings AP.

In the embodiment, each opening AP is provided with a wide viewing angle light-emitting unit and a narrow viewing angle light-emitting unit, and the narrow viewing angle light-emitting unit is disposed on a left side of the wide viewing angle light-emitting unit, but the disclosure is not limited thereto. In other embodiments, although not shown, the narrow viewing angle light-emitting unit may be disposed on a right side, upper side or lower side of the wide viewing angle light-emitting unit. In other embodiments, although not shown, each opening AP may be provided with one wide viewing angle light-emitting unit and two narrow viewing angle light-emitting units, and the two narrow viewing angle light-emitting units may be disposed on two opposite sides, such as upper and lower sides or left and right sides of the wide viewing angle light-emitting unit. In other embodiments, although not shown, each opening AP may be provided with a wide viewing angle light-emitting unit and a plurality of (such as two or more) narrow viewing angle light-emitting units, and the plurality of narrow viewing angle light-emitting units may be arranged around the wide viewing angle light-emitting unit. In other embodiments, although not shown, a plurality of (for example, more than two) narrow viewing angle light-emitting units may be disposed in each opening AP without any wide viewing angle light-emitting unit. The plurality of narrow viewing angle light-emitting units may be arranged along the direction X or the direction Y or arbitrarily arranged in the opening AP, and the plurality of narrow viewing angle light-emitting units are covered by the first light-shielding layer LS1.

Referring to FIG. 11 and FIG. 12, main differences between a light-emitting device 1G and the light-emitting device 1F of FIG. 9 and FIG. 10 are described below. In the light-emitting device 1G, the plurality of light-emitting units U are, for example, all blue light-emitting units UB, where the plurality of light-emitting units U (i.e., the plurality of light-emitting units U overlapping the plurality of light-transmitting openings AP′) exposed by the plurality of light-transmitting openings AP′ of the first light-shielding layer LS1 serve as the wide viewing angle light-emitting units, and the plurality of light-emitting units U shielded by the first light-shielding layer LS1 serve as narrow viewing angle light-emitting units. The plurality of wide viewing angle light-emitting units or the plurality of narrow viewing angle light-emitting units are provided in the same opening AP, and the plurality of light-emitting units U provided in the same opening AP are electrically connected in parallel with each other through a first electrode E1 and a second electrode E2 on the substrate SUB.

The insulating layer IN1 is embedded in the insulating layer IN2, and a material of the insulating layer IN1 may include, for example, an opaque material. The light-emitting device 1G further includes a second light-shielding layer LS2, a plurality of light conversion layers CVR, a plurality of light conversion layers CVG, a plurality of light-transmitting layers TP, and an insulating layer IN3. The second light-shielding layer LS2 is disposed on the insulating layer IN2 and includes a plurality of light-transmitting openings AP”. The plurality of light-transmitting openings AP″ are respectively disposed corresponding to the plurality of openings AP, and the plurality of light conversion layers CVR, the plurality of light conversion layers CVG and the plurality of light-transmitting layers TP are respectively filled in the plurality of light-transmitting openings AP″. The light conversion layers CVR are, for example, red light conversion layers, and the light conversion layers CVG are, for example, green light conversion layers. Materials of the red light conversion layers and the green light conversion layers may include fluorescence, phosphor, quantum dots, filter materials, other suitable light wavelength conversion materials, or combinations thereof. The light-transmitting layers TP are, for example, transparent insulating layers doped with light diffusion particles or blue filter layers. The insulating layer IN3 is disposed on the insulating layer IN2, the second light-shielding layer LS2, the plurality of light conversion layers CVR, the plurality of light conversion layers CVG, and the plurality of light-transmitting layers TP, and the first light-shielding layer LS1 is disposed on the insulating layer IN3.

Referring to FIG. 13, in a light-emitting device 1H, the plurality of light-emitting units

U may be divided into upper-layer light-emitting units (including the red light-emitting units UR and the blue light-emitting units UB) and lower-layer light-emitting units (including the green light-emitting units UG), and the first light-shielding layer LS1 may be fabricated together with pads (such as pads P3 and P4) of the upper light-emitting units.

In detail, the light-emitting device 1H may further include a first conductive layer C1. The first conductive layer C1 is disposed on the substrate SUB and may include a plurality of gate electrodes GE and a plurality of pads P1. A material of the first conductive layer C1 may include a transparent conductive material or an opaque conductive material. The transparent conductive material may include metal oxides, graphene, other suitable transparent conductive materials, or combinations thereof. The metal oxides may include indium tin oxide, indium zinc oxide, aluminum tin oxide, aluminum zinc oxide, indium germanium zinc oxide, or other metal oxides. The opaque conductive material may include metal, alloy, or a combination thereof.

The light-emitting device 1H may further include an insulating layer IN2. The insulating layer IN2 is disposed on the first conductive layer C1 and the substrate SUB. A material of the insulating layer IN2 includes, for example, an organic insulating material, an inorganic insulating material or a combination thereof. The organic insulating material, for example, includes polymethylmethacrylate (PMMA), epoxy, acrylic-based resin, silicone, polyimide polymer, or a combination thereof, but the disclosure is not limited thereto. The inorganic insulating material, for example, includes silicon oxide or silicon nitride, but the disclosure is not limited thereto.

The light-emitting device 1H may further include a semiconductor layer SCL. A material of the semiconductor layer SCL may include an oxide semiconductor material, such as indium gallium zinc oxide (IGZO), but the disclosure is not limited thereto. In other embodiments, a material of the semiconductor layer SCL may include amorphous silicon, polysilicon or metal oxide. The semiconductor layer SCL is, for example, a patterned semiconductor layer and may include a plurality of semiconductor patterns CHP. The semiconductor pattern CHP may include a channel region R1, a drain region R2, and a source region R3, where the channel region R1 is located between the drain region R2 and the source region R3 and overlaps the gate electrode GE in the direction Z.

The light-emitting device 1H may further include an insulating layer IN3. The insulating layer IN3 is disposed on the semiconductor layer SCL and the insulating layer IN2. A material of the insulating layer IN3 may refer to the material of the insulating layer IN2, which will not be repeated here.

The light-emitting device 1H may further include a second conductive layer C2. The second conductive layer C2 is disposed on the insulating layer IN3 and may include a plurality of source electrodes SE. A material of the second conductive layer C2 may refer to the material of the first conductive layer C1, which will not be repeated here. The source electrode SE may penetrate through the insulating layer IN3 for being electrically connected to one corresponding source region R3.

The light-emitting device 1H may further include an insulating layer IN4. The insulating layer IN4 is disposed on the second conductive layer C2 and the insulating layer IN3. A material of the insulating layer IN4 may refer to the material of the insulating layer IN2, which will not be repeated here.

The light-emitting device 1H may further include a third conductive layer C3. The third conductive layer C3 is disposed on the insulating layer IN4 and may include a plurality of drain electrodes DE and a plurality of pads P2. A material of the third conductive layer C3 may refer to the material of the first conductive layer C1, which will not be repeated here. The drain electrode DE may penetrate through the insulating layer IN4 and the insulating layer IN3 for being electrically connected to one corresponding drain region R2. The pad P2 may penetrate through the insulating layer IN4, the insulating layer IN3 and the insulating layer IN2 for being electrically connected to one corresponding pad P1.

The insulating layer IN1 is disposed on the insulating layer IN4, and the lower-layer light-emitting unit (including the green light-emitting unit UG) is disposed in the opening AP of the insulating layer IN1 and is electrically connected to a corresponding drain electrode DE and a corresponding pad P2. A material of the insulating layer IN1 may include, for example, an opaque material to reduce problems of light interference and/or light mixing.

The light-emitting device 1H may further include an insulating layer IN5. The insulating layer IN5 is filled in the plurality of openings AP of the insulating layer IN1. In some embodiments, an upper surface of the insulating layer IN5 may be aligned with the upper surface of the insulating layer IN1. A material of the insulating layer IN5 may include optical transparent glue or optical transparent resin, but the disclosure is not limited thereto.

The light-emitting device 1H may further include a fourth conductive layer C4. The fourth conductive layer C4 is disposed on the insulating layer IN5 and the insulating layer IN1 and may include a plurality of pads P3 and a plurality of pads P4. In some embodiments, the first light-shielding layer LS1 may be fabricated together with the plurality of pads P3 and the plurality of pads P4. Namely, the first light-shielding layer LS1 may belong to the fourth conductive layer C4 to save a number of process steps, but the disclosure is not limited thereto. A material of the fourth conductive layer C4 may refer to the material of the first conductive layer C1, which will not be repeated here. The pad P3 may penetrate through the insulating layer IN5 for being electrically connected to a corresponding drain electrode DE. The pad P4 may penetrate through the insulating layer IN5 for being electrically connected to a corresponding pad P2. The upper-layer light-emitting units (including the red light-emitting unit UR and the blue light-emitting unit UB) may be electrically connected to a plurality of active devices AD through the plurality of pads P3, and the upper-layer light-emitting units (including the red light-emitting unit UR and the blue light-emitting unit UB) may be electrically connected to an external circuit (such as a common power supply) through the plurality of pads P4, the plurality of pads P2, and the plurality of pads P1.

The light-emitting device 1H may further include an insulating layer IN6. The insulating layer IN6 is disposed on the upper-layer light-emitting units (including the red light-emitting unit UR and the blue light-emitting unit UB), the fourth conductive layer C4 and the insulating layer IN5. A material of the insulating layer IN6 may refer to the material of the insulating layer IN2, which will not be repeated here.

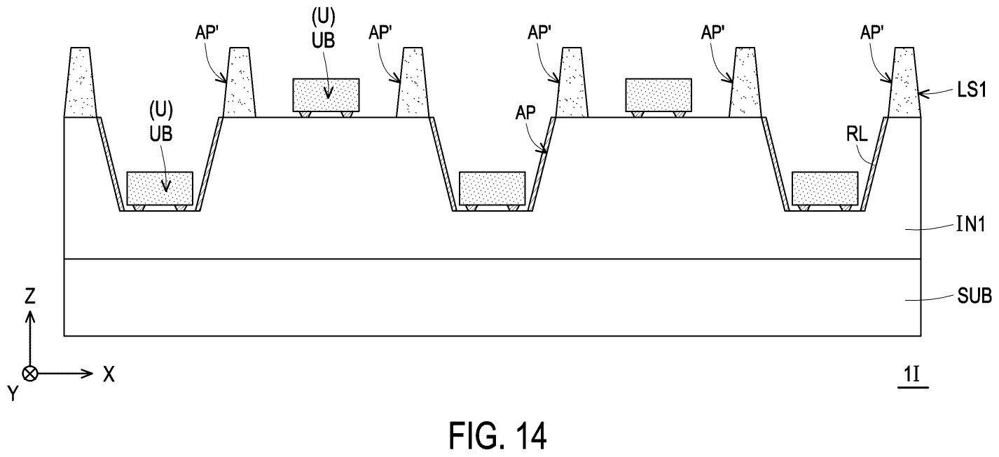

Referring to FIG. 14, in a light-emitting device 1I, the plurality of light-emitting units U are, for example, light-emitting units of a same color, such as blue light-emitting units UB, but the disclosure is not limited thereto. In other embodiments, the plurality of light-emitting units U may include light-emitting units of multiple colors.

The plurality of light-emitting units U include a plurality of upper-layer light-emitting units and a plurality of lower-layer light-emitting units, where a vertical distance between the upper-layer light-emitting units and the substrate SUB is greater than a vertical distance between the lower-layer light-emitting units and the substrate SUB. The plurality of lower light-emitting units are respectively located in the plurality of openings AP of the insulating layer IN1. The light-emitting device 1I may further include a reflective layer RL, and the reflective layer RL may be disposed on side walls of the plurality of openings AP. The first light-shielding layer LS1 is disposed on the insulating layer IN1, and the plurality of light-transmitting openings AP′ of the first light-shielding layer LS1 respectively overlap the plurality of upper-layer light-emitting units and the plurality of lower-layer light-emitting units in the direction Z.

In other embodiments, although not shown, the first light-shielding layer LS1 may be omitted. In other embodiments, although not shown, the plurality of light-emitting units U may be replaced from a plurality of LEDs to a plurality of organic LEDs.

In other embodiments, although not shown, the light-emitting device may include two stacked organic light-emitting display panels, where the upper organic light-emitting display panel may include an insulating layer/pixel definition layer. A plurality of openings of the insulating layer define a plurality of regions (such as a plurality of display regions and a plurality of light-transmitting regions), where the organic LEDs are disposed in the display regions. The organic LED includes a lower electrode, a light-emitting layer and an upper electrode. The lower electrode may be an opaque electrode so that light from the lower organic light-emitting display panel cannot pass through the display regions. The light-transmitting region is disposed between two adjacent display regions, and the light-transmitting region allows light from the lower organic light-emitting display panel to pass through. The lower organic light-emitting display panel may include another insulating layer/pixel definition layer. The plurality of openings in another insulating layer define a plurality of regions (such as a plurality display regions). The plurality display regions of the lower organic light-emitting display panel may respectively overlap with the plurality display regions and plurality of light-transmitting regions of the upper organic light-emitting display panel. Under such arrangement, the plurality of organic LEDs in the display regions of the lower organic light-emitting display panel may be turned on when the light-emitting device is in the narrow viewing angle mode and turned off when the light-emitting device is in the wide viewing angle mode. On the other hand, the plurality of organic LEDs in the plurality of display regions of the upper organic light-emitting display panel may be turned off when the light-emitting device is in the narrow viewing angle mode and turned on when the light-emitting device is in the wide viewing angle mode.

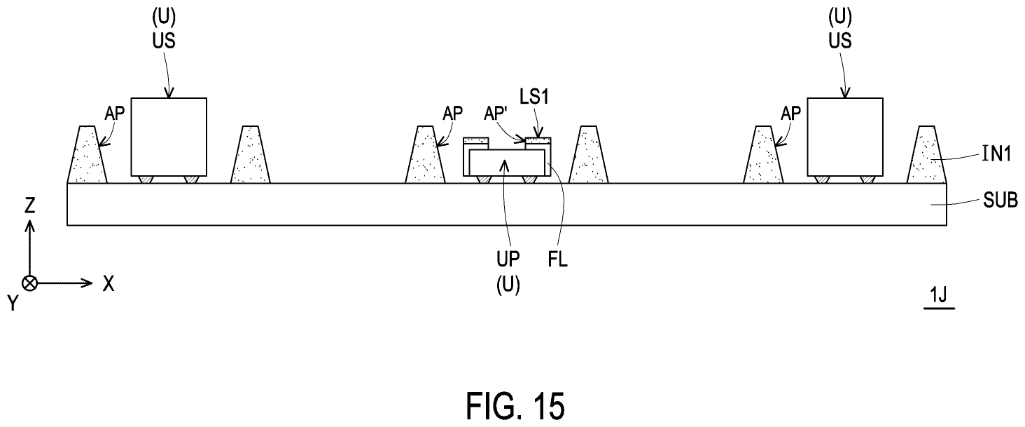

Referring to FIG. 15, in a light-emitting device 1J, the material of the insulating layer IN1 may include, for example, an opaque material. The plurality of light-emitting units U are respectively disposed in the plurality of openings AP of the insulating layer IN1. The plurality of light-emitting units U may be light-emitting units of the same color or include light-emitting units of multiple colors. In addition, the plurality of light-emitting units U may include a plurality of narrow viewing angle light-emitting units UP (only one is schematically shown) and a plurality of wide viewing angle light-emitting units US, where a light-emitting surface (or top surface) of the wide viewing angle light-emitting unit US may be high than a top surface of the insulating layer IN1, and a light-emitting surface (or top surface) of the narrow viewing angle light-emitting unit UP may be lower than the top surface of the insulating layer IN1. The light-emitting device 1J may further include a functional layer FL. The functional layer FL may be a light-absorbing layer or a reflective layer. The functional layer FL is, for example, disposed on a side wall surface of the narrow viewing angle light-emitting unit UP and on a part of the top surface of the narrow viewing angle light-emitting unit UP. The first light-shielding layer LS1 is disposed on the functional layer FL, and the light-transmitting opening AP′ of the first light-shielding layer LS1 exposes the narrow viewing angle light-emitting unit UP exposed by the functional layer FL.

In other embodiments, the opaque insulating layer IN1 may also be disposed only corresponding to the plurality of narrow viewing angle light-emitting units UP, and an anti-peep effect may be improved by increasing a thickness of the insulating layer IN1.

Referring to FIG. 16, in a light-emitting device 1K, the plurality of light-emitting units U may include a plurality of narrow viewing angle light-emitting units UP and a plurality of wide viewing angle light-emitting units US, where the narrow viewing angle light-emitting unit UP and the wide viewing angle light-emitting unit US respectively include a plurality of light-emitting units of various colors, such as red light-emitting unit UR, green light-emitting unit UG and blue light-emitting unit UB. Viewing from a top view, the red light-emitting unit UR, the green light-emitting unit UG and the blue light-emitting unit UB of the narrow viewing angle light-emitting unit UP may be jointly located in one light-transmitting opening AP′ of the first light-shielding layer LS1. In addition, the red light-emitting unit UR, the green light-emitting unit UG and the blue light-emitting unit UB of the wide viewing angle light-emitting unit US may be respectively located in the plurality of openings AP of the insulating layer IN1. In addition, one or more sensors SOR may be disposed in a region of the light-emitting device 1K where the narrow viewing angle light-emitting units UP and the wide viewing angle light-emitting units US are not provided.

It should be understood that the numbers and/or relative arrangement of the narrow viewing angle light-emitting units UP, the wide viewing angle light-emitting units US, the first light-shielding layer LS1 and the sensor SOR may be changed according to actual needs, and are not limited to what are shown in FIG. 16. In other embodiments, although not shown, the sensor SOR may be omitted. In other embodiments, although not shown, the red light-emitting unit UR, the green light-emitting unit UG and the blue light-emitting unit UB of the narrow viewing angle light-emitting unit UP may be respectively located in a plurality of light-transmitting openings AP′ of the first light-shielding layer LS1. In other embodiments, although not shown, the red light-emitting unit UR, the green light-emitting unit UG and the blue light-emitting unit UB of the wide viewing angle light-emitting unit US may be jointly located in one opening AP of the insulating layer IN1. In other embodiments, although not shown, the red light-emitting unit UR, the green light-emitting unit UG and the blue light-emitting unit UB of the narrow viewing angle light-emitting unit UP may be respectively located in a plurality of light-transmitting openings AP′ of the first light-shielding layer LS1, and the red light-emitting unit UR, the green light-emitting unit UG and the blue light-emitting unit UB of the wide viewing angle light-emitting unit US may be respectively located in the plurality of openings AP of the insulating layer IN1.

In summary, in the embodiments of the disclosure, by designing the first overlapping area to be different from the second overlapping area, an asymmetric viewing angle effect may be achieved.

The above embodiments are only used to illustrate the technical solution of the disclosure rather than limit it; although the disclosure has been described in detail with reference to the foregoing embodiments, those with ordinary knowledge in the technical field should understand that: the technical solutions described in the foregoing embodiments may still be modified, or some or all of the technical features may be equivalently substituted; and these modifications or substitutions do not cause the essence of the corresponding technical solutions to depart from the scope of the technical solutions of the embodiments of the disclosure.

Although the embodiments of the disclosure and advantages thereof have been disclosed above, it should be understood that anyone with ordinary knowledge in the art may make changes, substitutions and modifications without departing from the spirit and scope of the disclosure, and the features of various embodiments may be arbitrarily mixed and replaced with each other to form other new embodiments. In addition, a protection scope of the disclosure is not limited to the processes, machines, fabrications, material compositions, devices, methods and steps in the specific embodiments described in the specification, and anyone with ordinary knowledge in the relevant technical field may understand the current or future development of processes, machines, manufacturing, material compositions, devices, methods and steps currently or developed in the future, as long as the same functionality or results may be achieved in the embodiments described here, they may be used according to the present disclosure. Therefore, the protection scope of the disclosure includes the above-mentioned processes, machines, fabrications, material compositions, devices, methods and steps. In addition, each claim constitutes an individual embodiment, and the protection scope of the disclosure also includes a combination of each claim and embodiment. The protection scope of the disclosure shall be determined by the scope of the accompanying claims.

What is claimed is:

1. A light-emitting device, comprising:
a substrate;
an insulating layer, disposed on the substrate and comprising a first opening;
a first light-emitting unit, disposed in the first opening; and
a first light-shielding layer, disposed on the insulating layer,
wherein in a cross-sectional view, the first light-shielding layer comprises a first light-shielding portion and a second light-shielding portion adjacent to the first light-shielding portion, a first overlapping area of the first light-shielding portion is defined by a portion of the first light-shielding portion that overlaps the first opening, a second overlapping area of the second light-shielding portion is defined by a portion of the second light-shielding portion that overlaps the first opening, and the first overlapping area is different from the second overlapping area.

2. The light-emitting device as claimed in claim 1, wherein the insulating layer further comprises a second opening, and the light-emitting device further comprises:
a second light-emitting unit, disposed in the second opening,
wherein in another cross-sectional view, the first light-shielding layer further comprises a third light-shielding portion and a fourth light-shielding portion adjacent to the third light-shielding portion, a third overlapping area of the third light-shielding portion is defined by a portion of the third light-shielding portion that overlaps the second opening, a fourth overlapping area of the fourth light-shielding portion is defined by a portion of the fourth light-shielding portion that overlaps the second opening, and the third overlapping area is different from the fourth overlapping area.

3. The light-emitting device as claimed in claim 2, wherein a difference between the first overlapping area and the second overlapping area is different from a difference between the third overlapping area and the fourth overlapping area.

4. The light-emitting device as claimed in claim 2, wherein the light-emitting device comprises a narrow viewing angle mode and a wide viewing angle mode, when the light-emitting device is in the narrow viewing angle mode, the first light-emitting unit and the second light-emitting unit are turned on, and when the light-emitting device is in the wide viewing angle mode, the first light-emitting unit and the second light-emitting unit are turned off.

5. The light-emitting device as claimed in claim 2, wherein the substrate comprises a side, the first overlapping area is larger than the second overlapping area, the first overlapping area is closer to the side than the second overlapping area, the third overlapping area is larger than the fourth overlapping area, and the third overlapping area is closer to the side than the fourth overlapping area.

6. The light-emitting device as claimed in claim 2, wherein the substrate comprises a side, the first overlapping area is less than the second overlapping area, the first overlapping area is closer to the side than the second overlapping area, the third overlapping area is larger than the fourth overlapping area, and the third overlapping area is closer to the side than the fourth overlapping area.

7. The light-emitting device as claimed in claim 2, wherein the first light-emitting unit and the second light-emitting unit emit light of different colors.

8. The light-emitting device as claimed in claim 1, wherein the insulating layer further comprises a second opening, and the light-emitting device further comprises:
a second light-emitting unit, disposed in the second opening,
wherein the light-emitting device comprises a narrow viewing angle mode and a wide viewing angle mode, when the light-emitting device is in the narrow viewing angle mode, the first light-emitting unit is turned on and the second light-emitting unit is turned off, and when the light-emitting device is in the wide viewing angle mode, the first light-emitting unit is turned off and the second light-emitting unit is turned on.

9. The light-emitting device as claimed in claim 8, wherein
in the cross-sectional view, the insulating layer comprises a first insulating portion and a second insulating portion adjacent to the first insulating portion, and the first light-emitting unit is disposed between the first insulating portion and the second insulating portion,
in another cross-sectional view, the insulating layer comprises a third insulating portion and a fourth insulating portion adjacent to the third insulating portion, and the second light-emitting unit is disposed between the third insulating portion and the fourth insulating portion,
wherein a reflectivity of at least one of the third insulating portion and the fourth insulating portion is greater than a reflectivity of at least one of the first insulating portion and the second insulating portion.

10. The light-emitting device as claimed in claim 8, wherein
in the cross-sectional view, the insulating layer comprises a first insulating portion and a second insulating portion adjacent to the first insulating portion, and the first light-emitting unit is disposed between the first insulating portion and the second insulating portion,
in another cross-sectional view, the insulating layer comprises a third insulating portion and a fourth insulating portion adjacent to the third insulating portion, and the second light-emitting unit is disposed between the third insulating portion and the fourth insulating portion,
wherein a slope of a side wall of at least one of the first insulating portion and the second insulating portion is greater than a slope of a side wall of at least one of the third insulating portion and the fourth insulating portion.

11. The light-emitting device as claimed in claim 8, further comprising:
a reflective layer, wherein in another cross-sectional view, the insulating layer comprises a third insulating portion and a fourth insulating portion adjacent to the third insulating portion, the second light-emitting unit is disposed between the third insulating portion and the fourth insulating portion, and the reflective layer is disposed on a side wall of at least one of the third insulating portion and the fourth insulating portion.

12. The light-emitting device as claimed in claim 8, wherein
in the cross-sectional view, the insulating layer comprises a first insulating portion between the first light-emitting unit and the second light-emitting unit and at least partially overlapping the second light-shielding portion,
in the cross-sectional view, a third overlapping area of the second light-shielding portion is defined by a portion of the second light-shielding portion that overlaps the second opening, and the third overlapping area is different from the second overlapping area.

13. The light-emitting device as claimed in claim 12, wherein the third overlapping area is less than the second overlapping area.

14. The light-emitting device as claimed in claim 1, wherein in the cross-sectional view, a maximum width of the first opening is measured at a position higher than the first light-emitting unit.

15. The light-emitting device as claimed in claim 1, further comprising:
a second light-shielding layer, disposed between the insulating layer and the first light-shielding layer, wherein in the cross-sectional view, the second light-shielding layer comprises a third light-shielding portion and a fourth light-shielding portion adjacent to the third light-shielding portion, a third overlapping area of the third light-shielding portion is defined by a portion of the third light-shielding portion that overlaps the first opening, a fourth overlapping area of the fourth light-shielding portion is defined by a portion of the fourth light-shielding portion that overlaps the first opening, and the third overlapping area is different from the fourth overlapping area.

16. The light-emitting device as claimed in claim 15, further comprising:
a light conversion layer, disposed on the substrate, wherein at least a part of the light conversion layer is disposed between the first light-shielding portion and the second light-shielding portion.

17. The light-emitting device as claimed in claim 1, further comprising:
a second light-emitting unit, disposed in the first opening.
